(19) United States
(12) Patent Application Publication
(10) Pub. No.: US 2016/0149106 A1
(43) Pub. Date: May 26, 2016

(54) THERMOELECTRIC DEVICE

(71) Applicant: Samsung Electronics Co., Ltd., Suwon-si (KR)

(72) Inventors: Wooram HONG, Yongin-si (KR); Eunkyung LEE, Seoul (KR); Byounglyong CHOI, Seoul (KR)

(21) Appl. No.: 14/701,121

(22) Filed: Apr. 30, 2015

(30) Foreign Application Priority Data
Nov. 26, 2014 (KR) 10-2014-0166443

(51) Int. Cl. H01L 35/30

(52) U.S. Cl. CPC H01L 35/30

(57) ABSTRACT

A thermoelectric device including a heat supplier, a thermoelectric element disposed on the heat supplier, and a heat exchanger disposed opposite to the heat supplier, where the thermoelectric element is disposed between the heat supplier and the heat exchanger. In the thermoelectric device, the heat exchanger include a medium adsorptive part defined on a surface thereof, and the medium adsorptive part is exposed outside to contact with a first medium of the air and has an adsorptive property for a second medium including a fluid and different from the first medium.

### CROSS-REFERENCE TO RELATED APPLICATIONS

This application claims priority to Korean Patent Application No. 10-2014-0166443 filed on Nov. 26, 2014, and all the benefits accruing therefrom under 35 U.S.C. §119, the content of which in its entirety is herein incorporated by reference.

### BACKGROUND

1. Field

Embodiments of the invention relate to a thermoelectric device.

2. Description of the Related Art

The thermoelectric device is a device using the Seebeck effect, which is a phenomenon generating an electromotive force using a temperature difference occurring in nature, an artifact such as a machine, a building, and the like. The thermoelectric conversion means energy conversion between thermal energy and electrical energy. When temperatures are different at respective ends of a thermoelectric material, a temperature gradient occurs between the ends thereof, and electricity is generated by a current flowing to the thermoelectric material.

Using the Seebeck effect, heat generated from a computer, an automobile engine, or the like may be converted into electrical energy, and using the Peltier effect, various cooling systems may be accomplished without using a coolant. As new energy development, waste energy recycling, protection of the environment, and the like are drawing a lot of attention, interest in thermoelectric devices is also increasing.

On the other hand, as the use of various portable electronic devices such as a smart phone, a tablet personal computer (“PC”), a personal digital assistant (“PDA”) has recently increased, such techniques may be used to enhance portability of the electronic devices and to simply supply energy for the portable electronic devices.

### SUMMARY

One embodiment increases thermoelectric efficiency by effectively supplying a medium into a heat exchanger to maximize a temperature difference generated in a thermoelectric element.

According to an embodiment, a thermoelectric device includes a heat supplier, a thermoelectric element disposed on the heat supplier, and a heat exchanger disposed opposite to the heat supplier, where the thermoelectric element is disposed between the heat supplier and the heat exchanger. In such an embodiment, the heat exchanger comprises a medium adsorptive part defined on a surface thereof, and the medium adsorptive part is exposed outside to contact with a first medium of air and has an adsorptive property to a second medium including a fluid and different from the first medium.

In an embodiment, the heat exchanger has a structure which allows the second medium to be directly supplied into the medium adsorptive part without passing through an additional channel.

In an embodiment, the second medium may have a higher convective heat transfer coefficient than a convective heat transfer coefficient of the first medium.

In an embodiment, the heat exchanger has a structure which allows the second medium to be supplied into a heat exchanger by impregnating, spraying, scattering, pouring, coating or a combination thereof.

In an embodiment, the medium adsorptive part may have a three-dimensional shape including a recess portion, a protruding portion, or a combination thereof.

In an embodiment, the recess portion or the protruding portion may have a dimple having a size of several micrometers (μm) to several hundred micrometers (μm).

In an embodiment, the medium adsorptive part may include a coating layer having a plurality of nanopatterns.

In an embodiment, the second medium may be a liquid, and an interval between adjacent nanopatterns of the nanopatterns may correspond to a droplet size of the liquid.

In an embodiment, the second medium may be a liquid, and when the liquid is supplied to the heat exchanger, the liquid may fill a space defined between the adjacent nanopatterns of the nanopatterns, and an interface surface between the liquid and air has a concave curved shape.

In an embodiment, the medium adsorptive part may include a porous material.

In an embodiment, the temperature of the heat exchanger may be lowered based on a phase change of the second medium adsorbed thereto.

In an embodiment, the thermoelectric device may further include a protective body disposed on the heat exchanger.

In an embodiment, the protecting body may have transmittance with respect to the second medium.

In an embodiment, the protecting body may have a mesh structure.

In an embodiment, the thermoelectric device may further include a protecting member disposed between the thermoelectric element and the heat supplier or between the thermoelectric element and the heat exchanger.

In an embodiment, the thermoelectric device may further include an insulating member disposed on the thermoelectric element.

In an embodiment, the thermoelectric element and the insulating member may be spaced apart from each other.

In an embodiment, the thermoelectric device may include a wearable device attachable to or detachable from a body of a user.

In an embodiment, heat supplied from the heat supplier to the medium adsorptive part may be generated based on a body temperature of the user.

In an embodiment, the second medium supplied to the medium adsorptive part may have mobility according to a motion of the user.

In embodiments of the invention, the thermoelectric device may effectively and efficiently obtain energy in a short time by using the air and fluid and different from the first medium, e.g., other than the air, for the convective heat transport.

### BRIEF DESCRIPTION OF THE DRAWINGS

The above and other features of the invention will become more apparent by describing in detailed exemplary embodiments thereof with reference to the accompanying drawings, in which:

FIG. 1 is a cross-sectional view showing an embodiment of a thermoelectric device according to the invention;

FIG. 2 is a cross-sectional view enlarging an “A” portion of an embodiment of a thermoelectric device shown in FIG. 1 according to the invention;

FIG. 3 is a cross-sectional view enlarging the “A” portion of an alternative embodiment of a thermoelectric device shown in FIG. 1 according to the invention;

FIG. 4 is a cross-sectional view enlarging the “A” portion of another alternative embodiment of a thermoelectric device shown in FIG. 1 according to the invention.

FIG. 5 is a cross-sectional view enlarging the “A” portion of yet another alternative embodiment of a thermoelectric device shown in FIG. 1 according to the invention;

FIG. 6 is a cross-sectional view showing a bump structure in a protruding portion of an embodiment of a heat exchanger according to the invention;

FIG. 7 is a cross-sectional view showing a bump structure in a recess portion of an alternative embodiment of a heat exchanger according to the invention;

FIG. 8 is a cross-sectional view showing an embodiment of a heat exchanger according to the invention;

FIG. 9 is a cross-sectional view showing an alternative embodiment of a heat exchanger according to the invention;

FIG. 10 is a cross-sectional view of an embodiment of a thermoelectric device according to the invention;

FIG. 11 is a cross-sectional view of an alternative embodiment of a thermoelectric device according to the invention;

FIG. 12 is a cross-sectional view of another embodiment of a thermoelectric device according to the invention; and

FIGS. 13 to 16 are cross-sectional views of embodiments of thermoelectric devices according to the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

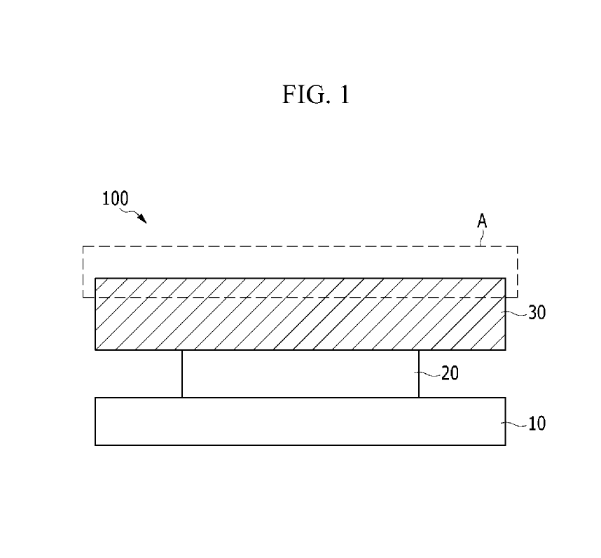

An embodiment of a thermoelectric device according to the invention will be described with reference to FIG. 1.

FIG. 1 is a cross-sectional view showing an embodiment of a thermoelectric device according to the invention. Referring to FIG. 1, an embodiment of the thermoelectric device 100 includes a heat supplier 10, a thermoelectric element 20 disposed on the heat supplier 10 (e.g., on a side or surface of the heat supplier 10), and a heat exchanger 30 disposed on the thermoelectric element 20 (e.g., on a side or surface of the thermoelectric element 20).

The thermoelectric device 100 is a device that obtains energy using a temperature difference of the thermoelectric element 20, where the thermoelectric element 20 includes a high temperature portion having a relatively high temperature and a low temperature portion having a relatively low temperature. In an embodiment of the thermoelectric device 100, N-type and P-type semiconductor materials are arranged between the high temperature portion and the low temperature portion of the thermoelectric element 20, so energy may be produced according to the principle that electrons are transported in the N-type material and holes are transported in the P-type material by the temperature difference between the high temperature portion and the low temperature portion to generate electricity. Materials of the thermoelectric element 20 may include any material that provides a temperature difference, for example, a Bi—Sb—Te-based material, at a room temperature range, but are not limited thereto. The high temperature portion of the thermoelectric element 20 may be disposed on one side of the heat supplier 10, and the low temperature portion of the thermoelectric element 20 may be disposed on one side of the heat exchanger 30.

The heat supplier 10 may supplies heat to the thermoelectric device 100. In one embodiment, for example, the heat supplier 100 may be a body of a person or animal when the thermoelectric device 100 is attached to the person's or animal's body or the like. In such an embodiment, energy may be obtained by using the thermoelectric phenomenon from the body temperature of the person or animal under the room temperature atmosphere without an additional cooling or heating device.

An embodiment of the thermoelectric device 100 may be a wearable device attached or detached to the user's body, and specifically, an Internet of Things (“IoT”) based device such as a smart phone, a smart watch, or the like.

A surface or a side of the heat exchanger 30 is disposed opposite to, e.g., facing, the thermoelectric element 20 and forms a temperature difference of greater than or equal to a predetermined level in the thermoelectric element 20 by a heat exchange operation with the outside. The heat exchanger 30 may emit heat of the low temperature portion to the outside using, for example, a convection current of the low temperature portion of the thermoelectric element 20.

In an embodiment, a first surface or a first side of the heat exchanger 30 is disposed (e.g., exposed outside) to contact with a first medium of the air, and the first surface or the first side of the heat exchanger 30 in contact with the air has an adsorptive property with respect to a second medium including a fluid and different from the first medium, e.g., other than the air. The portion that has an adsorptive property with respect to the second medium on the first surface or the first side of heat exchanger 30 defines a medium adsorptive portion (A).

Adsorption is a phenomenon in which a concentration at an interface of a material is higher than a concentration thereof at the surroundings. The heat exchanger 30 may use a fluid other than the air as well as the air as a convective medium of the low temperature portion of the thermoelectric element 20 by including a part having an adsorptive property with respect to the fluid other than the air on the first surface thereof, such that the efficiency of the thermoelectric device 100 may be increased.

In an embodiment, the fluid of the second medium may be in a gas phase, a liquid phase, a plasma phase or a combination thereof, and may include any material that generates a phase change by the convection current. In one embodiment, for example, the second medium may be a material having a higher convective heat transfer coefficient (h) or a higher convective heat transfer coefficient (hc) than the first medium, and may include, for example, a liquid such as water, an alcohol, and an oil.

In an embodiment, where a surface or a side of the heat exchanger 30 is positioned to contact the air, as described above, the thermoelectric device 100 has a structure that is open to the outside. Accordingly, in such an embodiment, the air and the fluid other than the air may be effectively supplied into the heat exchanger 30, to frequently induce the heat radiation of the low temperature portion of the thermoelectric element 20. In one embodiment, for example, the fluid other than the air may be supplied into the heat exchanger 30 by impregnation, spraying, scattering, coating, pouring or a combination thereof, but is not limited thereto.

In an embodiment of the thermoelectric device 100, the medium other than the air supplied to the heat exchanger 30 may be directly supplied into the medium adsorptive portion without passing through an additional channel. In one embodiment, for example, where the thermoelectric device 100 is a smart phone, the user may induce a decrease in temperature of the low temperature portion of the thermoelectric element 20 based on a phase change by directly inputting a liquid material acquirable in the surrounding environment, such as an alcohol, into the heat exchanger 30. Thereby, the thermoelectric element 20 provides a temperature difference for a short time so that the thermoelectric device 100 may rapidly obtain energy. In such an embodiment, the thermoelectric device 100 may be directly supplied with the medium without the additional channel, such that energy may be rapidly obtained compared to a system supplied with the medium through a fluid path. Accordingly, in such an embodiment, energy may be rapidly and efficiently obtained in an emergency such as an accident.

In general, the arrangement of the device may be restricted by gravity to operate the capillary phenomenon for passing a fluid in a system adopting a fluid path. In an embodiment of the thermoelectric device 100 according to the invention, as the fluid other than the air is adsorbed directly on the surface of the heat exchanger 30 without using the additional channel such as the fluid path, the thermoelectric phenomenon may occur in the thermoelectric device 100 even when the thermoelectric device 100 is arranged in a direction other than the gravity direction. In such an embodiment, the thermoelectric phenomenon may occur in the thermoelectric device 100 at greater than or equal to a predetermined level regardless of the user's motion.

In one embodiment, for example, the second medium may have mobility according to the user's motion. In an embodiment, where the thermoelectric device 100 is, for example, a smart watch, the distribution (adsorption degree) of the second medium on the medium adsorptive portion may be changed according to wrist motion of the user. Therefore, the motion intended by a user may allow the adsorptive degree of second medium to be substantially uniform on the medium adsorptive portion, such that thermoelectric efficiency may increases.

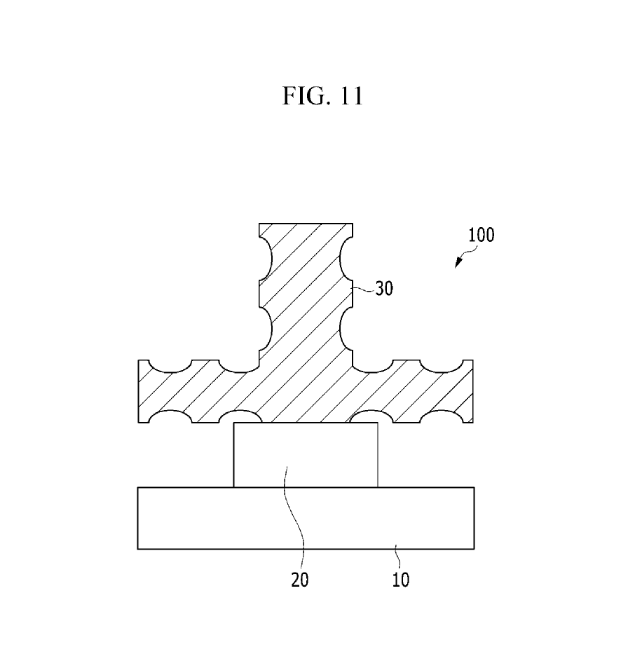

The medium adsorptive portion A is defined or formed on a surface or a side of the heat exchanger 30. In one embodiment, for example, the medium adsorptive portion A may be formed on a surface (e.g., the first surface) opposite to a surface (e.g., a second surface) of the heat exchanger 30 that faces the thermoelectric element 20. In an alternative embodiment, considering the heat exchanged degree, among the surfaces where the heat exchanger 30 faces the thermoelectric element 20, medium adsorptive portions may be defined on the other regions contacting the air may be, for example, medium adsorptive portions may be defined on one side or both sides of the heat exchanger 30 as shown in FIG. 11.

The medium adsorptive portion may have any material or structure that causes the phase change by temporarily adsorbing the second medium on the heat exchanger 30, and the material or the structure thereof is not limited to specific material or structure. In one embodiment, for example, the medium adsorptive portion may be formed with a porous material such as fibers or a sponge. In an alternative embodiment, the medium adsorptive portion may be formed with a gelatinous material such as agar. In another alternative embodiment, the medium adsorptive portion may include metals, carbon materials, polymer-included materials, cotton materials or combinations thereof.

In one embodiment, For example, the medium adsorptive portion may have a three-dimensional space structure including a recess portion, a protruding portion or a combination thereof, and may have a shape such as a wave, lattice, dimple, honeycomb or a combination thereof, but is not limited thereto.

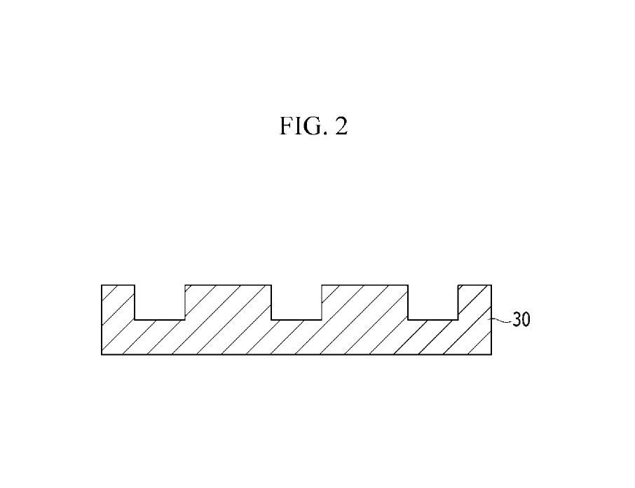

The three-dimensional space structure of the medium adsorptive portion of an embodiment of the thermoelectric device 100 will hereinafter be described in greater detail with reference to FIGS. 2 to 5.

FIGS. 2 to 5 are cross-sectional views enlarging an “A” part of embodiments of the thermoelectric device 100 shown in FIG. 1.

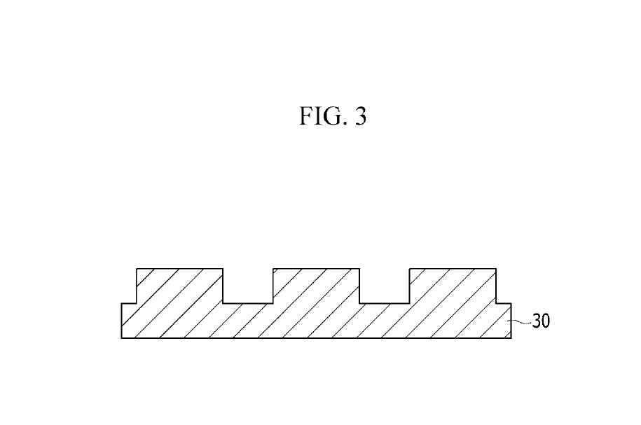

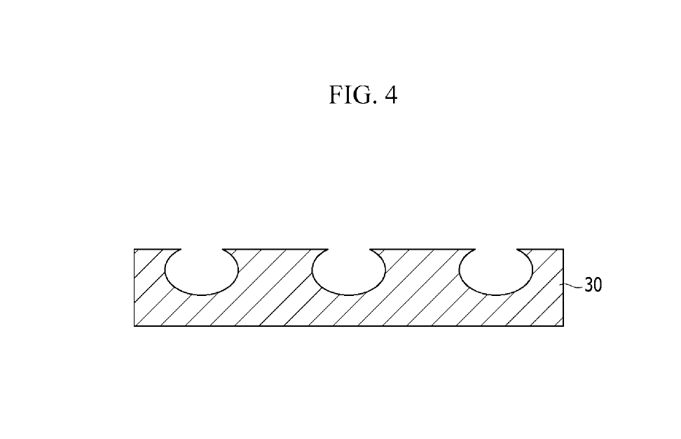

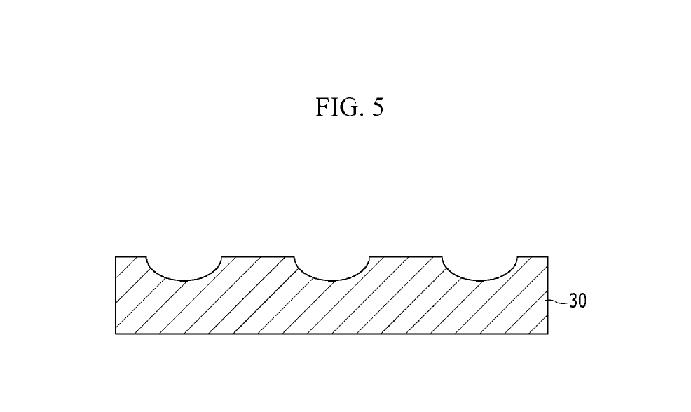

In one embodiment, for example, the medium adsorptive portion of heat exchanger 30 has an uneven recess structure ( [symbol] ) as shown in FIG. 2. In one alternative embodiment, for example, the medium adsorptive portion of heat exchanger 30 has an uneven protruding structure ( [symbol] ) as shown in FIG. 3. FIGS. 2 and 3 show embodiments where the medium adsorptive portion has an uneven structure having a recess portion and a protruding portion, but the invention is not limited thereto. In such an embodiment, the detail structure of the medium adsorptive portion is not limited to those shown FIGS. 2 and 3 as long as a three-dimensional space structure is formed. In one embodiment, for example, as shown in FIGS. 4 and 5, the medium adsorptive portion of the heat exchanger 30 may have a recess portion having a cross-sectional surface with a wave shape. In such embodiment shown in FIGS. 2 to 5, each recess portion and protruding portion may be regular or irregular.

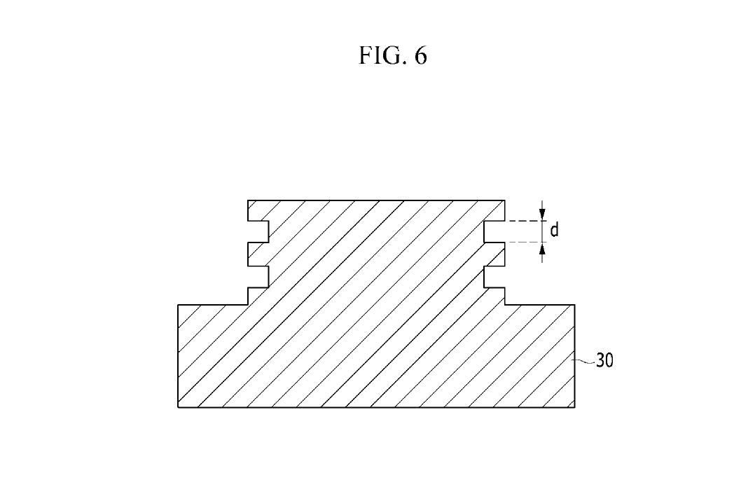

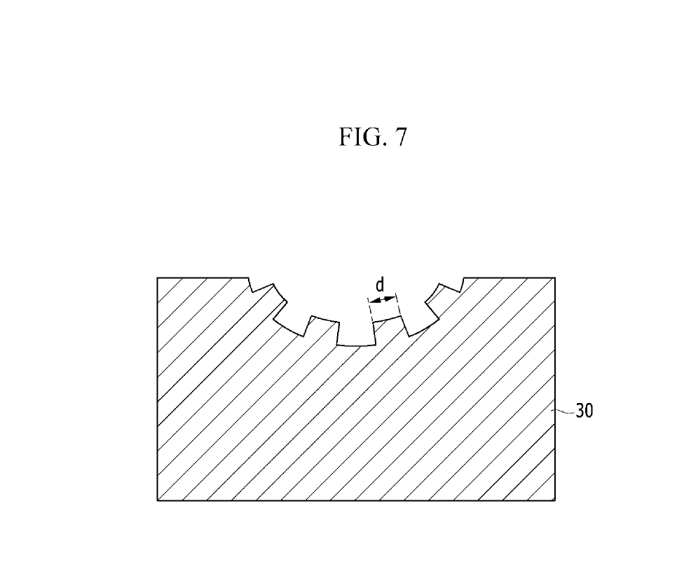

In an alternative embodiment, the recess portion or the protruding portion may have a dimple having a size of several micrometers (μm) to several hundred micrometers (μm). Hereinafter, such embodiments will be described in greater detail with reference to FIG. 6 and FIG. 7.

FIG. 6 is a cross-sectional view showing a dimple structure formed on the protruding portion of an embodiment of the heat exchanger 30 according to the invention, and FIG. 7 is a cross-sectional view showing a dimple structure formed on the recess portion of an alternative embodiment of the heat exchanger 30 according to the invention.

Referring to FIGS. 6 and 7, as the heat exchanger 30 has a micro-dimple structure having a size (d) of several micrometers (μm) to several hundred micrometers (μm), the degree of the second medium being adsorbed into the medium adsorptive portion of the heat exchanger 30 may be increased. FIG. 6 shows a concave micro-bump structure formed on the protruding portion and FIG. 7 shows a convex micro-bump structure formed on the recess portion, but the structure may be variously modified based on the kind of the second medium supplied to the heat exchanger 30 and the material of the medium adsorptive portion of the heat exchanger 30. When the micro-sized uneven structure is formed, the area where a basic unit droplet of the liquid medium contacts the surface of the heat exchanger 30 is increased by the dimple, so that the liquid medium may be adhered to the surface of the heat exchanger 30 at a high viscosity. Accordingly, in such an embodiment, the phase change may be accelerated by uniformly adhering small droplets on the surface of the heat exchanger to maximize the entire surface area of all droplets.

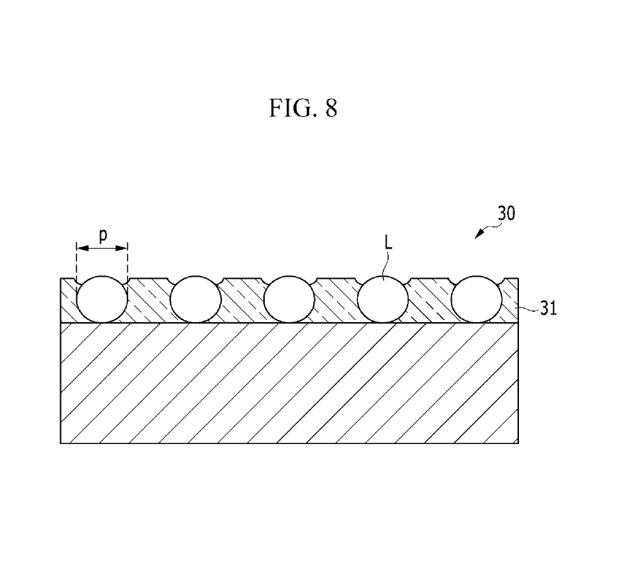

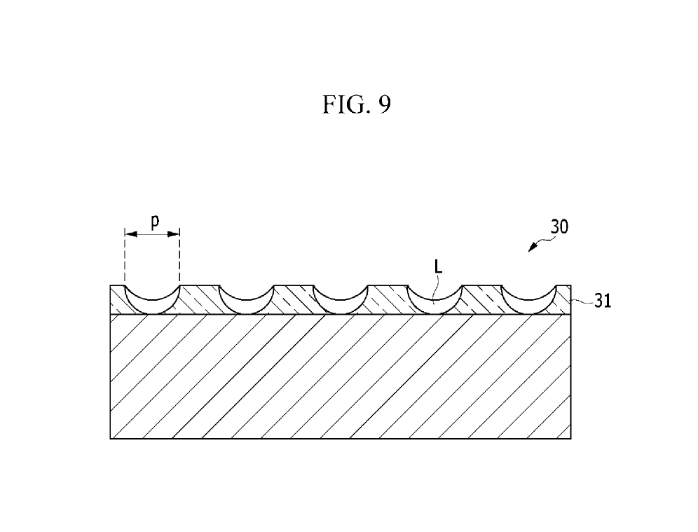

FIGS. 8 and 9 are cross-sectional views showing alternative embodiments of a heat exchanger 30 according to the invention.

Referring to FIGS. 8 and 9, in an alternative embodiment, the heat exchanger 30 may include a coating layer 31 having a plurality of nanopatterns, and the coating layer 31 may define a medium adsorptive portion of the heat exchanger 30. In such an embodiment, the nanopattern may be holes, recess portions or protruding portions having a size of several nanometers to several hundred nanometers, or a combination thereof, and the shape thereof or the like is not particularly limited. In such an embodiment, where the heat exchanger 30 has a nano-sized pattern, the strength of adsorbing the second medium onto the heat exchanger 30 may be increased. In one embodiment, for example, as the intermolecular attractive force and/or repulsive force between the material of a coating layer 31 and the second medium may be determined based on the characteristics of the material of the coating layer 31 and the pattern of the coating layer 31, the shape of droplets, the surface area of droplets, the adsorptive degree of the second medium and the like may be controlled by modifying the material of a coating layer 31 capable of suitable associating the attractive force and/or the repulsive force with the second medium and the pattern of the coating layer 31, considering the properties of the second medium.

Referring to FIG. 8, in an embodiment, the second medium may be a liquid (L), and the droplet size of the liquid (L) may correspond to a gap (p) between adjacent nanopatterns. In one embodiment, for example, the liquid (L) may be water, and the coating layer 31 may be a hydrophobic material such as TEFLON™ (i.e., polytetrafluoroethylene). In such an embodiment, the hydrophobic material has a repellent property to water, so water forms droplets to increase the surface area of the water.

Referring to FIG. 9, in an alternative embodiment, the second medium may be a liquid (L), a part of a space between the adjacent nanopatterns may be filled with the liquid (L), and the interface of the liquid (L) and the air may have a curved shape. In one embodiment, for example, the liquid (L) may be water, and the coating layer 31 may be a hydrophilic material. In such an embodiment, as a hydrophilic material has property of drawing water, the medium (e.g., water) may be fixed on the surface of the heat exchanger 30 for a longer time by increasing the absorbability of water.

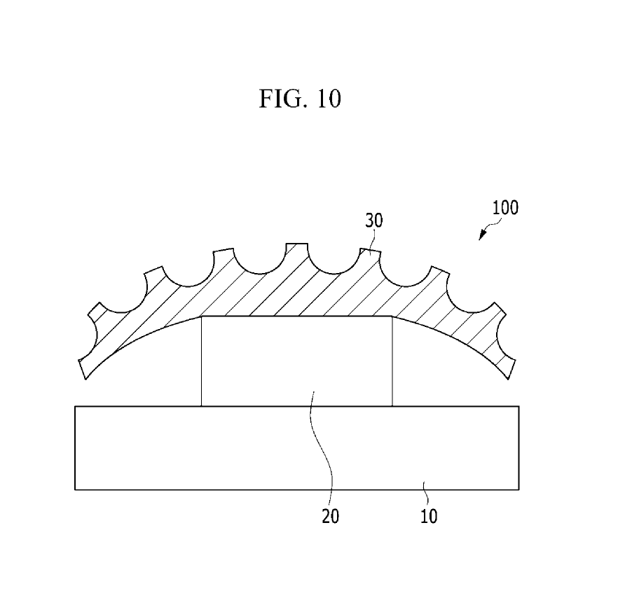

The structure of the heat exchanger 30 is not limited to those described above, and may include, for example, a flat structure, a curved structure, or a combination thereof. FIG. 10 is a cross-sectional view showing an alternative embodiment of a thermoelectric device according to the invention. As shown in FIG. 10, the heat exchanger 30 may have a curved shape bending to the lower end. FIG. 11 is a cross-sectional view showing another alternative embodiment of a thermoelectric device according to the invention. As shown in FIG. 11, the heat exchanger 30 may have a multi-dimensional space structure. In such embodiments of the heat exchangers 30 shown in FIG. 10 and FIG. 11, as the heat exchanger 30 increases the area contacting the air, the contacting area to the air (first medium) and the fluid (second medium) except the air is increased to further enhance the heat exchanged amount at the heat exchanger 30. Accordingly, in such an embodiment, the thermoelectric efficiency of the thermoelectric device 100 may be increased by increasing the temperature difference of thermoelectric element 20.

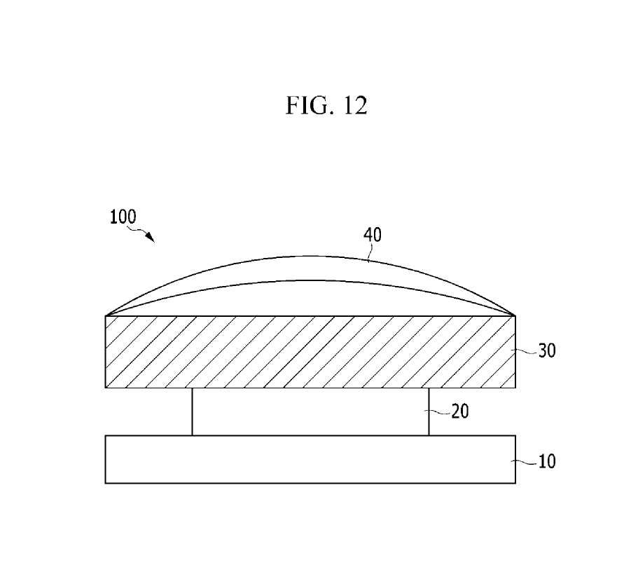

FIG. 12 is a cross-sectional view showing another alternative embodiment of a thermoelectric device according to the invention. Referring to FIG. 12, in an embodiment, the thermoelectric device 100 may further include a protecting body 40 disposed on the heat exchanger 30.

In such an embodiment, the protecting body 40 may include or be formed with a material and/or a structure having transmittance to the second medium. The protecting body 40 may be fabricated with, for example, a metal material or a plastic material, and may have a shape of, for example, a mesh structure. In such an embodiment, the thermoelectric device 100 includes the protecting body 40 to effectively prevent the second medium adsorbed onto the heat exchanger 30 from being detached. In such an embodiment, where the protecting body 40 has transmittance for the second medium, the medium may be input into the heat exchanger 30 through the protecting body 40 even if not removing the protecting body 40, such that the medium (e.g., the second medium) other than the air may be easily and frequently supplied into the thermoelectric device 100.

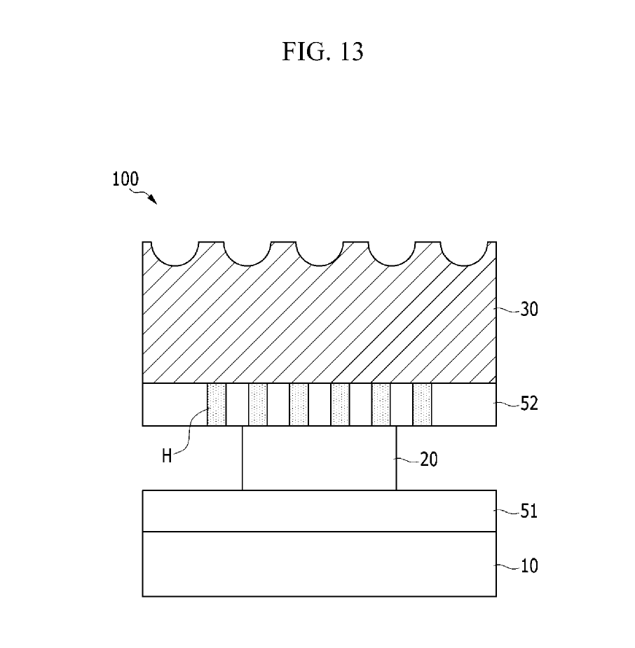

FIGS. 13 to 16 are cross-sectional views showing various alternative embodiments of thermoelectric devices 100 according to the invention.

Referring to FIG. 13, an embodiment of the thermoelectric device 100 may further include protecting members 51 and 52 disposed between the thermoelectric element 20 and the heat supplier 10 and/or between the thermoelectric element 20 and the heat exchanger 30. The protecting members 51 and 52 may include or be made of, for example, stainless steel or nylon and the like and may have a thickness in a range of, for example, about 50 micrometers to about 500 micrometers, but are not limited thereto. The protecting members 51 and 52 may have, for example, a thermal via structure in which a heat pipe (H) is formed therethrough toward the thermoelectric element 20, e.g., in a vertical direction.

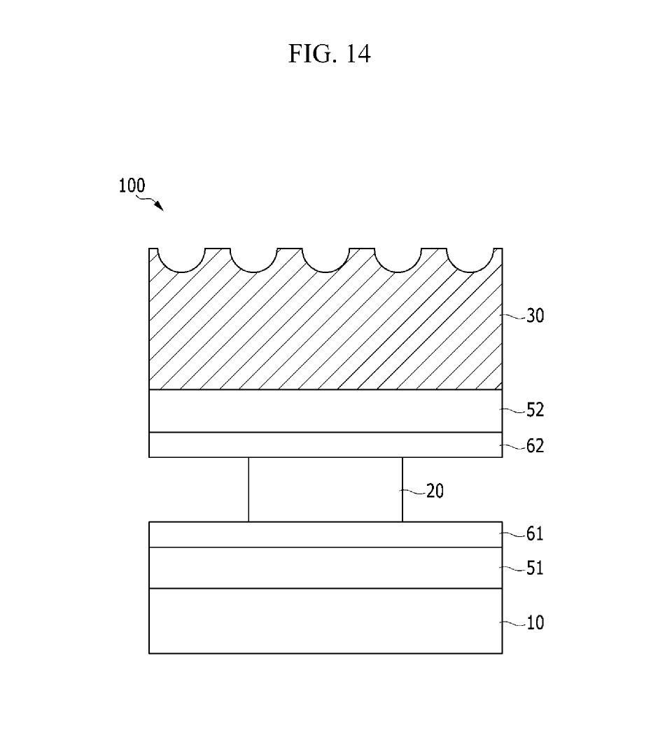

Referring to FIG. 14, an embodiment of the thermoelectric device 100 may further include thermal interface materials (“TIM”) 61 and 62 disposed between the thermoelectric element 20 and the protecting member 51 and/or the thermoelectric element 20 and the protecting member 52.

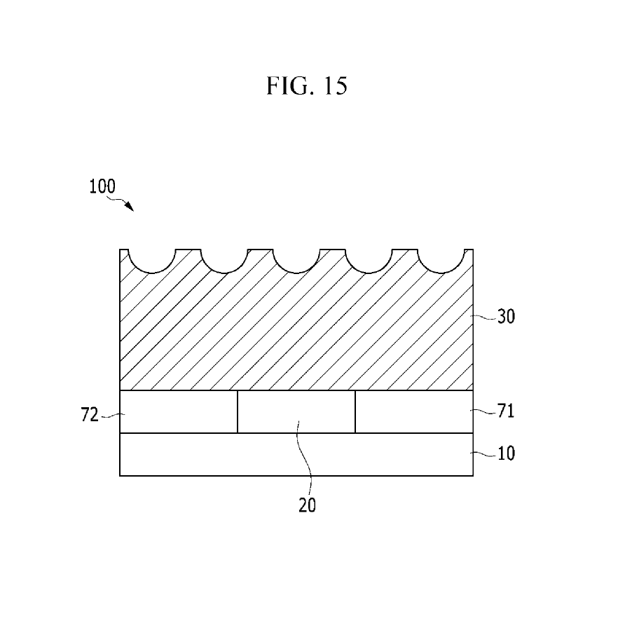

Referring to FIG. 15, an embodiment of the thermoelectric device 100 may further include insulating members (e.g., an insulating layer) 71 and 72 disposed on a surface or a side (e.g., side surfaces) of the thermoelectric element 20. In such an embodiment, the insulating members 71 and 72, and the thermoelectric element 20 may be disposed in a same layer on the heat supplier 10. In such an embodiment, the insulating members 71 and 72 may surround the thermoelectric element 20.

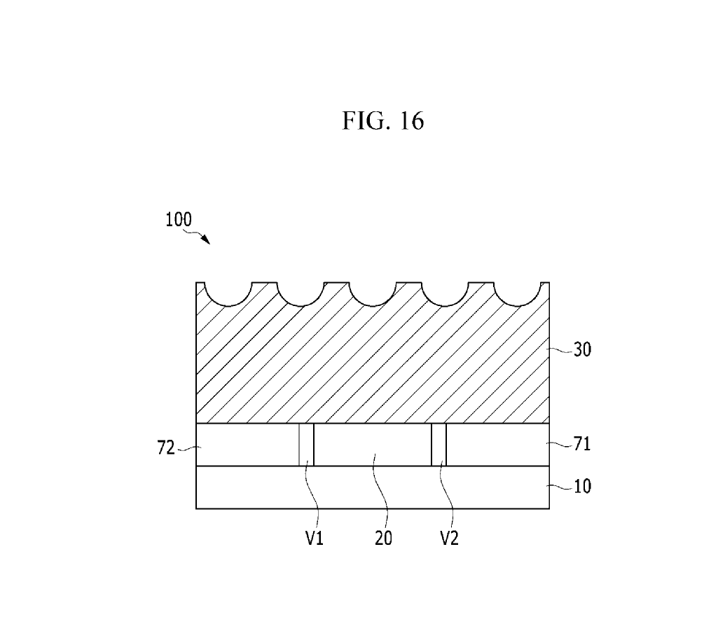

Referring to FIG. 16, an embodiment of the thermoelectric element 20 and the insulating members 71 and 72 may be disposed on the heat supplier 10, and spaced apart from each other. In one embodiment, for example, spaces V1 and V2 between the thermoelectric element 20 and the insulating members 71 and 72 may be filled with air or be in a vacuum state.

Embodiments of the thermoelectric devices according to the invention may effectively obtain energy in a short time by using the first medium and the second medium for the convection heat transport.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thermoelectric device comprising:
a heat supplier;
a thermoelectric element disposed on the heat supplier; and
a heat exchanger disposed opposite to the heat supplier, wherein the thermoelectric element is disposed between the heat supplier and the heat exchanger,
wherein the heat exchanger comprises a medium adsorptive part defined on a surface thereof,
wherein the medium adsorptive part is exposed outside to contact with a first medium of air, and has an adsorptive property to a second medium comprising a fluid and different from the first medium.

2. The thermoelectric device of claim 1, wherein the heat exchanger has a structure which allows the second medium to be directly supplied into the medium adsorptive part without passing through an additional channel.

3. The thermoelectric device of claim 1, wherein the second medium has a higher convective heat transfer coefficient than a convective heat transfer coefficient of the first medium.

4. The thermoelectric device of claim 1, wherein the heat exchanger has a structure which allows the second medium to be supplied to the heat exchanger by impregnating, spraying, scattering, pouring, coating, or a combination thereof.

5. The thermoelectric device of claim 1, wherein the medium adsorptive part has a three-dimensional shape comprising a recess portion, a protruding portion or a combination thereof.

6. The thermoelectric device of claim 5, wherein the recess portion or the protruding portion has a dimple having a size of several micrometers to several hundred micrometers.

7. The thermoelectric device of claim 1, wherein the medium adsorptive part comprises a coating layer having a plurality of nanopatterns.

8. The thermoelectric device of claim 7, wherein
the second medium is a liquid, and
a gap between adjacent nanopatterns of the nanopatterns corresponds to a droplet size of the liquid.

9. The thermoelectric device of claim 7, wherein
the second medium is a liquid,
when the liquid is supplied to the heat exchanger, the liquid fills a space defined between the adjacent nanopatterns of the nanopatterns, and an interface surface between the liquid and the air has a concave curved shape.

10. The thermoelectric device of claim 1, wherein the medium adsorptive part comprises a porous material.

11. The thermoelectric device of claim 1, wherein the temperature of the heat exchanger is lowered based on a phase change of the second medium adsorbed thereto.

12. The thermoelectric device of claim 1, further comprising:
a protecting body disposed on the heat exchanger.

13. The thermoelectric device of claim 12, wherein the protecting body has transmittance with respect to the second medium.

14. The thermoelectric device of claim 13, wherein the protecting body has a mesh structure.

15. The thermoelectric device of claim 1, further comprising:
a protecting member disposed between the thermoelectric element and the heat supplier or between the thermoelectric element and the heat exchanger.

16. The thermoelectric device of claim 1, further comprising:
an insulating member disposed on the thermoelectric element.

17. The thermoelectric device of claim 16, wherein the thermoelectric element and the insulating member are spaced apart from each other.

18. The thermoelectric device of claim 1, wherein the thermoelectric device comprises a wearable device attachable to or detachable from a body of a user.

19. The thermoelectric device of claim 18, wherein heat supplied from the heat supplier to the medium adsorptive part is generated based on a body temperature of the user.

20. The thermoelectric device of claim 19, wherein the second medium supplied to the medium adsorptive part has mobility according to a motion of the user.
